(19) United States
(12) Patent Application Publication
(10) Pub. No.: US 2024/0304547 A1
(43) Pub. Date: Sep. 12, 2024

(54) WIRING STRUCTURE FOR ADVANCED INTERCONNECT

(71) Applicant: INTERNATIONAL BUSINESS MACHINES CORPORATION, ARMONK, NY (US)

(72) Inventors: Oscar van der Straten, Guilderland Center, NY (US); Linda W Wangoh, Cohoes, NY (US); Chih-Chao Yang, Glenmont, NY (US)

(21) Appl. No.: 18/179,421

(22) Filed: Mar. 7, 2023

(51) Int. Cl. H01L 23/528; H01L 21/768; H01L 23/532

(52) U.S. Cl. CPC H01L 23/5283; H01L 21/76837; H01L 21/76877; H01L 21/76885; H01L 23/53266

(57) ABSTRACT

Embodiments of present invention provide a wiring structure. The wiring structure includes a metal line in a dielectric layer, where the metal line has a first sidewall and a second sidewall opposite the first sidewall and, from a bottom to a top thereof, includes at least a first section and a second section, where first and second sidewalls of the first section lean outwards from a bottom to a top of the first section, and first and second sidewalls of the second section lean inwards from a bottom to a top of the second section. A method of manufacturing the wiring structure is also provided.

### BACKGROUND

The present application relates to manufacturing of semiconductor integrated circuits. More particularly, it relates to a multifaceted wiring structure and method of manufacturing the same.

An integrated circuit such as a semiconductor wafer or a device chip typically includes front-end-of-line (FEOL), middle-of-line (MOL), and back-end-of-line (BEOL) structures. Particularly, several metal levels with each level including various metal lines may be formed in a BEOL structure for power supplies and signal routing and/or interconnect. For a BEOL with pitch size below 30 nm, R/C related signal delay may become unsustainably large resulting in such need or current trend to fill metal lines, particularly those with minimum CD, with non-copper conductive material (such as ruthenium) during their metallization process in order to lower the overall resistance of these metal lines. However, dielectric line wiggling which may be caused by metal stress is still a big concern and such concern becomes even more obvious when it involves filling trenches with high aspect ratio to form the metal lines.

### SUMMARY

Embodiments of present invention provide a wiring structure. The wiring structure includes a metal line in a dielectric layer, the metal line having a first sidewall and a second sidewall opposite the first sidewall, the first and second sidewalls having a zigzag shape and not being straight along a vertical direction. By being in a zigzag shape, the metal line is able to maintain a reasonable width from a bottom to a top thereof, with small variations, while having a high aspect ratio.

In one embodiment, the metal line, from a bottom to a top thereof, includes at least a first section and a second section with their respective first and second sidewalls, where the first and second sidewalls of the first section lean outwards from a bottom to a top of the first section, and the first and second sidewalls of the second section lean inwards from a bottom to a top of the second section. The inward-leaning sidewalls of the second section return the width of the metal line at the top of the second section to approximately the width of the metal line at the bottom of the first section, thereby avoiding creating a metal line structure that has a continuously expanding width from a bottom to a top thereof.

In another embodiment, the metal line further includes a third section directly above the second section and a fourth section directly above the third section, where the third section has its first and second sidewalls and the first and second sidewalls of the third section lean outwards from a bottom to a top of the third section, and the fourth section has its first and second sidewalls and the first and second sidewalls of the fourth section lean inwards from a bottom to a top of the fourth section. Similarly, the inward-leaning sidewalls of the fourth section return the width of the metal line at the top of the fourth section to approximately the width of the metal line at the bottom of the third section, to continue maintaining a reasonably constant, with small variations, width.

In one embodiment, the first and second sidewalls of the first section extend continuously into the first and second sidewalls of the second section, the first and second sidewalls of the second section extend continuously into the first and second sidewalls of the third section, and the first and second sidewalls of the third section extend continuously into the first and second sidewalls of the fourth section.

In another embodiment, the first sidewall of the first section forms an angle between −30 degrees and −45 degrees with a normal to a bottom surface of the first section, and the second sidewall of the first section forms an angle between 30 degrees and 45 degrees with the normal to the bottom surface of the first section.

In one embodiment, the first section, the second section, the third section, and the fourth section are surrounded, respectively, by a first dielectric layer, a second dielectric layer, a third dielectric layer, and a fourth dielectric layer, where the first dielectric layer is materially different from the second dielectric layer, the second dielectric layer is materially different from the third dielectric layer, and the third dielectric layer is materially different from the fourth dielectric layer.

According to one embodiment, the wiring structure further includes a first barrier layer between the first section and the first dielectric layer and a second barrier layer between the second section and the second dielectric layer, where the first barrier layer is materially different from the second barrier layer.

In one embodiment, the first barrier layer is made of titanium-nitride and the second barrier layer is made of tantalum-nitride.

Embodiments of present invention also provide a method of forming a wiring structure. The method includes forming a first dielectric layer on top of a supporting structure, the first dielectric layer having one or more openings therein; filling the one or more openings with a first conductive material to form a first section of a metal line in the first dielectric layer; patterning a second conductive material on top of the first section of the metal line to form a second section of the metal line; forming a second dielectric layer surrounding the second section of the metal line; forming a third dielectric layer on top of the second section of the metal line, the third dielectric layer having one or more openings therein; filling the one or more openings in the third dielectric layer with a third conductive material to form a third section of the metal line in the third dielectric layer; patterning a fourth conductive material on top of the third section of the metal line to form a fourth section of the metal line; and forming a fourth dielectric layer surrounding the fourth section of the metal line, thereby forming the metal line of the wiring structure. Through this multi-patterning process, one or more metal lines may be created that may be able to maintain a reasonable width from a bottom to a top thereof, with small zigzag variations, while having an overall high aspect ratio.

### BRIEF DESCRIPTION OF THE DRAWINGS

The present invention will be understood and appreciated more fully from the following detailed description of embodiments of present invention, taken in conjunction with accompanying drawings of which:

FIGS. 1-17 are demonstrative illustrations of cross-sectional view of a wiring structure in a process of manufacturing thereof according to embodiments of a method of present invention; and

FIG. 18 is a demonstrative illustration of a flow-chart of a method of manufacturing a wiring structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

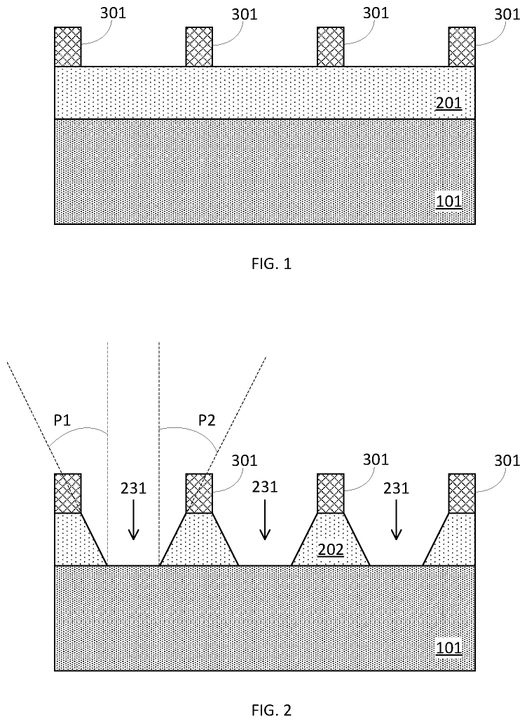

FIG. 1 is a demonstrative illustration of cross-sectional view of a wiring structure in a step of manufacturing thereof according to one embodiment of a method of present invention. More particularly, embodiments of present invention provide receiving or providing a supporting structure 101 which may be, for example, a part of a back-end-of-line (BEOL) structure, a middle-of-line (MOL) structure, a front-end-of-line (FEOL) structure, or a semiconductor substrate. When being a semiconductor substrate, the semiconductor substrate may be a silicon (Si) substrate, a silicon-germanium (SiGe) substrate, a silicon-on-insulator (SOI) substrate, a silicon-germanium-on-insulator (SGOI), or any other suitable substrate.

Next, embodiments of present invention provide forming a wiring structure on top of the supporting structure 101. The wiring structure may include one or more metal lines, and the one or more metal lines may be formed, according to embodiments of present invention, by forming multiple sections of the one or more metal lines. In one embodiment, the multiple sections may include a first section, a second section, a third section and a fourth section that are stacked one on top of another. The multiple sections of the one or more metal lines may be formed through a damascene patterning process, a subtractive patterning process, or a combination of the damascene patterning process and the subtractive patterning process.

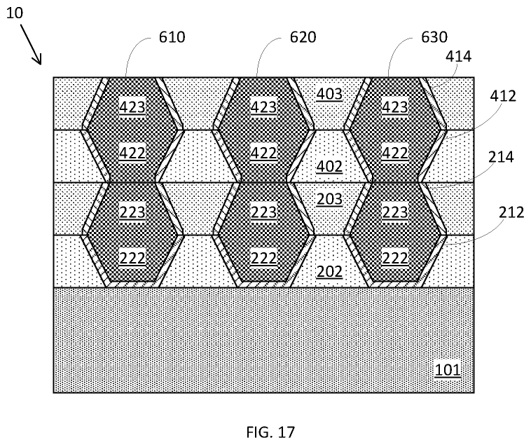

Embodiments of present invention provide forming a first section of a metal line, such as a metal line 630 (see FIG. 17), among the one or more metal lines 610, 620, and 630 through a damascene patterning process. More particularly, embodiments of present invention provide forming a raw dielectric layer 201 on top of the supporting structure 101. The raw dielectric layer 201 may be formed through a deposition process such as a chemical-vapor-deposition (CVD) process, a plasma-enhanced chemical-vapor-deposition (PECVD) process, an atomic-layer-deposition (ALD) process, a physical-vapor-deposition (PVD) process, and other currently existing or future developed processes. The raw dielectric layer 201 may be a low-k dielectric layer including, for example, organic polymer low-k dielectric, carbon-doped oxide including, for example, SiCOH and SiCNOH.

Embodiments of present invention further provide forming a first hard mask 301 on top of the raw dielectric layer 201. The first hard mask 301 may include a pattern of one or more openings for forming the metal line in the raw dielectric layer 201.

FIG. 2 is a demonstrative illustration of cross-sectional view of a wiring structure in a step of manufacturing thereof according to one embodiment of a method of present invention. More particularly, following the step illustrated in FIG. 1, embodiments of present invention provide etching the raw dielectric layer 201 to form a first dielectric layer 202 that has one or more openings 231 therein. The etching process may be a selective and directional etching process, such as an ion-beam etching (IBE) process or a reactive-ion etching (RIE) process. The openings 231 created thereby, with the first hard mask 301 covering portions of the raw dielectric layer 201 during the etching process, may have slant sidewalls such as a slant left sidewall and a slant right sidewall as being illustrated in FIG. 2. The openings 231 may be made through the raw dielectric layer 201 to expose the underneath supporting structure 101.

The slant sidewalls of the openings 231 may form angles with a normal to a bottom surface of the openings 231, which later may become a bottom surface of the metal line to be formed hereinafter. For example, as is illustrated in FIG. 2, the slant left sidewall and the normal to the bottom surface of the openings 231 may form an angle P1 that may be between −30 degrees and −45 degrees, with the minus meaning an angle measured counterclockwise from the normal. On the other hand, the slant right sidewall and the normal to the bottom surface of the one or more openings 231 may an angle P2 that may be between 30 degrees and 45 degrees, meaning an angle measured clockwise from the normal.

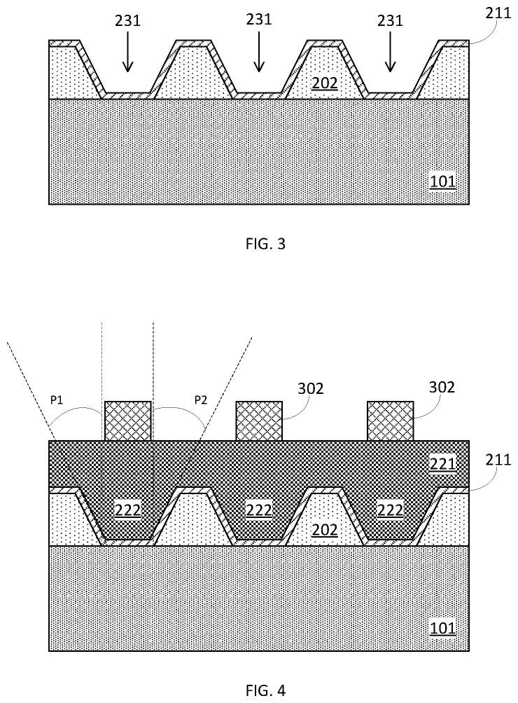

FIG. 3 is a demonstrative illustration of cross-sectional view of a wiring structure in a step of manufacturing thereof according to one embodiment of a method of present invention. More particularly, following the step illustrated in FIG. 2, embodiments of present invention provide removing the first hard mask 301 through, for example, a resist lifting process and subsequently forming a first raw barrier layer 211 to cover the first dielectric layer 202 and exposed top surfaces of the supporting structure 101. The first raw barrier layer 211 may be a conformal layer of, for example, titanium-nitride (TiN), tantalum-nitride (TaN), zirconium-nitride (ZrN), titanium-zirconium-nitride (TiZrN) and may be formed through an ALD process. The first raw barrier layer 211 may protect the first dielectric layer 202 from being contaminated by conductive material of the first section of the metal line to be formed in the openings 231. In other words, the first raw barrier layer 211 may prevent the conductive material of the first section of the metal line from diffusing into the first dielectric layer 202.

FIG. 4 is a demonstrative illustration of cross-sectional view of a wiring structure in a step of manufacturing thereof according to one embodiment of a method of present invention. More particularly, following the step illustrated in FIG. 3, embodiments of present invention provide depositing a conductive material into the openings 231 to form a first section 222 of the metal line. The conductive material of the first section 222 may be, for example, ruthenium (Ru), molybdenum (Mo), Iridium (Ir), cobalt (Co), tungsten (W), or other suitable materials. By following the shapes of the openings 231, a cross-section of the first section 222 may have a trapezoidal shape with a short base at a bottom and a long base at a top. The left sidewall of the first section 222 and a normal to a bottom surface of the first section 222 may form an angle P1, similar to the angle P1 in FIG. 2, that may be between −30 degrees and −45 degrees. The right sidewall of the first section 222 and the normal to the bottom surface of the first section 222 may form an angle P2, similar to the angle P2 in FIG. 2, that may be between 30 degrees and 45 degrees. In other words, the first section 222 may have a first sidewall (e.g., the left sidewall) and a second sidewall (e.g., the right sidewall) that lean outwards from a bottom to a top of the first section 222.

The openings 231 may have a relatively small aspect ratio, when being compared with the conventional art where when a trench opening is created to form a metal line, the trench opening may have an aspect ratio as high as four times the aspect ratio of the openings 231. By virtue of the small aspect ratio, when depositing the conductive material in the openings 231 to form the first section 222, there is little or no metal gap-fill concern or line wiggling concern.

Embodiments of present invention provide further depositing a conductive layer 221 on top of the first section 222 and above the first dielectric layer 202 via the first raw barrier layer 211. The conductive layer 221 may be made of a same conductive material as that of the first section 222. However, embodiments of present invention are not limited in this aspect and different conductive material may be used for the conductive layer 221 and the first section 222. In one embodiment, the conductive layer 221 may be deposited through, for example, an ALD process, and may be made to have a thickness that is comparable or similar to that of the first section 222. For example, the conductive layer 221 and the first section 222 may be made to have a thickness difference less than about 10%. The small difference in thicknesses helps facilitate the process of forming multiple sections of the metal line with relative ease as being described below in more details.

After forming the conductive layer 221, embodiments of present invention provide forming a second hard mask 302 on top of the conductive layer 221. The second hard mask 302 may be formed to be significantly aligned with the bottom surface of the first section 222. In addition, the second hard mask 302 may be formed to have a width that is about the same as a width of the bottom surface of the first section 222.

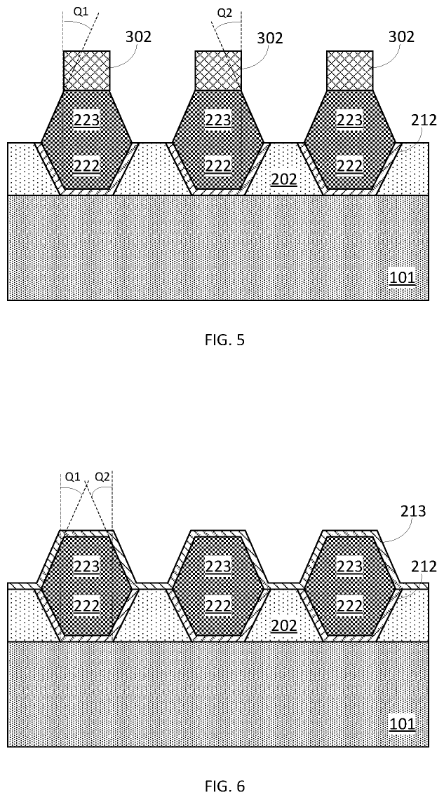

FIG. 5 is a demonstrative illustration of cross-sectional view of a wiring structure in a step of manufacturing thereof according to one embodiment of a method of present invention. More particularly, following the step illustrated in FIG. 4, embodiments of present invention provide forming a second section 223 of the metal line through a subtractive patterning process by etching portions of the conductive layer 221 that are not covered by the second hard mask 302 until the underneath first dielectric layer 202 is exposed. The etching process may be a selective and directional etching process, such as an IBE or a RIE process, and the formed second section 223 may have slant sidewalls such as a slant left sidewall and a slant right sidewall as is illustrated in FIG. 5. The etching process may also remove portions of the first raw barrier layer 211 that are directly above the first dielectric layer 202, thereby creating a first barrier layer 212 lining sidewalls and bottom surfaces of the first section 222.

The slant sidewalls of the second section 223 may form angles with the normal to the bottom surface of the first section 222. For example, as is illustrated in FIG. 5, the slant left sidewall of the second section 223 and the normal to the bottom surface of the first section 222 may form an angle Q1, and the angle Q1 may be between 30 degrees and 45 degrees, meaning an angle measured clockwise from the normal. On the other hand, the slant right sidewall of the second section 223 and the normal to the bottom surface of the first section 222 may form an angle Q2, and the angle Q2 may be between −30 degrees and −45 degrees, with the minus meaning an angle measured counterclockwise from the normal. In one embodiment, the second section 223 may have a trapezoidal shape with a long base at a bottom and a short base at a top. The second section 223 may have first and second sidewalls (e.g., the left sidewall and the right sidewall) that lean inwards from a bottom to a top of the second section 223.

Since the conductive layer 221 has a thickness that is approximately the same as that of the first section 222, and the second hard mask 302 has a width that is approximately the same as the bottom surface of the first section 222, etching the conductive layer 221 using the second hard mask 302 may create the second section 223 that has a bottom surface that is significantly close in size to the top surface of the first section 222. In other words, the long base of the trapezoidal shape representing the cross-section of the first section 222 may be significantly same in length as the long base of the trapezoidal shape representing the cross-section of the second section 223, and the first and second sidewalls of the first section 222 may extend continuously into the first and second sidewalls of the second section 223.

FIG. 6 is a demonstrative illustration of cross-sectional view of a wiring structure in a step of manufacturing thereof according to one embodiment of a method of present invention. More particularly, following the step illustrated in FIG. 5, embodiments of present invention provide removing the second hard mask 302 through, for example, a resist lifting process and subsequently forming a second raw barrier layer 213 covering the second section 223 and the exposed top surface of the first dielectric layer 202. The second raw barrier layer 213 may be a conformal layer of, for example, TiN, TaN, ZrN, TiZrN and may be formed through an ALD process. In one embodiment, the second raw barrier layer 213 may be materially same or different from the first raw barrier layer 211. For example, the first raw barrier layer 211 may be made of TiN and the second raw barrier layer 213 may be made of TaN. The second raw barrier layer 213 may prevent the conductive material of the second section 223 from diffusing into a second dielectric layer that may be formed to surround the second section 223, as being described below in more details. As is illustrated in FIG. 6, the inward-leaning sidewalls of the second section 223 return the width of the metal line 610 at the top of the second section 223 to approximately the width of the metal line 610 at the bottom of the first section 222, thereby avoiding creating a metal line structure that, otherwise, may have a continuously expanding width from a bottom to a top thereof.

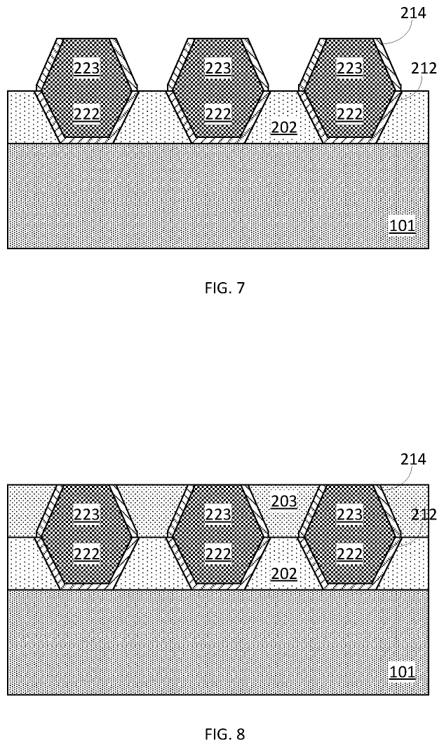

FIG. 7 is a demonstrative illustration of cross-sectional view of a wiring structure in a step of manufacturing thereof according to one embodiment of a method of present invention. More particularly, following the step illustrated in FIG. 6, embodiments of present invention provide applying a directional etching process that selectively removes portions of the second raw barrier layer 213 that are substantially horizontal. For example, the directional etching process may remove portions of the second raw barrier layer 213 that are on a top surface of the second section 223 and that are on top of the first dielectric layer 202, thereby creating a second barrier layer 214 that surrounds the sidewalls of the second section 223. In one embodiment, since the bottom surface of the second section 223 is significantly same in size as the top surface of the first section 222, the first barrier layer 212 may extend continuously into the second barrier layer 214. Similar to the fact that the first and second sidewalls of the first section 222 extend continuously into the first and second sidewalls of the second section 223.

FIG. 8 is a demonstrative illustration of cross-sectional view of a wiring structure in a step of manufacturing thereof according to one embodiment of a method of present invention. More particularly, following the step illustrated in FIG. 7, embodiments of present invention provide forming a second dielectric layer 203 surrounding, via the second barrier layer 214, sidewalls of the second section 223. For example, the second dielectric layer 203 may be formed through a selective deposition process where dielectric material of the second dielectric layer 203 may be formed selectively on top of exposed top surfaces of the first dielectric layer 202 and on top of the exposed second barrier layer 214 and not, at least not meaningfully, on the top surface of the second section 223 that are not dielectric material. However, embodiments of present invention are not limited in this aspect. For example, the second dielectric layer 203 may be formed through one or more other processes such as a CVD process, a PECVD process, an ALD process, or a PVD process. After forming the second dielectric layer 203 by using the selective deposition process, a chemical-mechanic-polishing (CMP) process may be applied to planarize the top surface of the second dielectric layer 203 and make the top surface of the second dielectric layer 203 coplanar with the top surface of the second section 223. The second dielectric layer 203 may be materially different from the first dielectric layer 202. For example, the first dielectric layer 202 may be SiCOH and the second dielectric layer 203 may be SiCNOH.

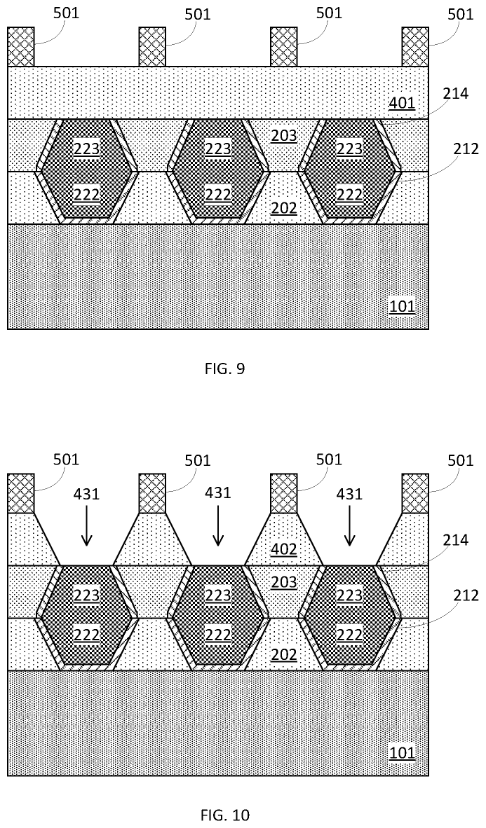

FIG. 9 is a demonstrative illustration of cross-sectional view of a wiring structure in a step of manufacturing thereof according to one embodiment of a method of present invention. More specifically, following the step illustrated in FIG. 8, embodiments of present invention provide forming a third section and a fourth section of the metal line in a manner similar to that of forming the first section 222 and the second section 223 of the metal line.

More particularly, embodiments of present invention provide forming a third section of the metal line through a damascene patterning process. More specifically, embodiments of present invention provide forming a raw dielectric layer 401 on top of the second section 223 and the second dielectric layer 203. The raw dielectric layer 401 may be formed through a CVD process, a PECVD process, an ALD process, or a PVD process and may be a low-k dielectric layer including, for example, organic polymer low-k dielectric, carbon-doped oxide including, for example, SiCOH and SiCNOH. Embodiments of present invention further provide forming a third hard mask 501 on top of the raw dielectric layer 401. The third hard mask 501 may include one or more openings that are centrally aligned with the second section 223 underneath the raw dielectric layer 401.

FIG. 10 is a demonstrative illustration of cross-sectional view of a wiring structure in a step of manufacturing thereof according to one embodiment of a method of present invention. More particularly, following the step illustrated in FIG. 9, embodiments of present invention provide etching the raw dielectric layer 401 to form a third dielectric layer 402 that has one or more openings 431 therein. The openings 431 may have slant sidewalls such as a slant left sidewall and a slant right sidewall as is illustrated in FIG. 10. The openings 431 expose the underneath second section 223.

In one embodiment, embodiments of present invention provide forming the raw dielectric layer 401 to have a thickness that is approximately same as that of the raw dielectric layer 201 and forming the third hard mask 501 to have one or more openings that are significantly similar to those of the first hard mask 301, the openings 431 created through the etching process may have a size, at a bottom thereof, that are significantly similar to and aligned with the top surfaces of the second section 223.

Similar to the openings 231 and the angles P1 and P2 as illustrated in FIG. 2, the slant sidewalls of the openings 431 may form angles with the normal to the bottom surface of the first section 222. For example, an angle P1 may be formed by the slant left sidewall of the openings 431 and the normal to the bottom surface of the first section 222 to have an angle valued between −30 degrees and −45 degrees. Further for example, an angle P2 may be formed by the slant right sidewall of the openings 431 and the normal to the bottom surface of the first section 222 to have an angle valued between 30 degrees and 45 degrees.

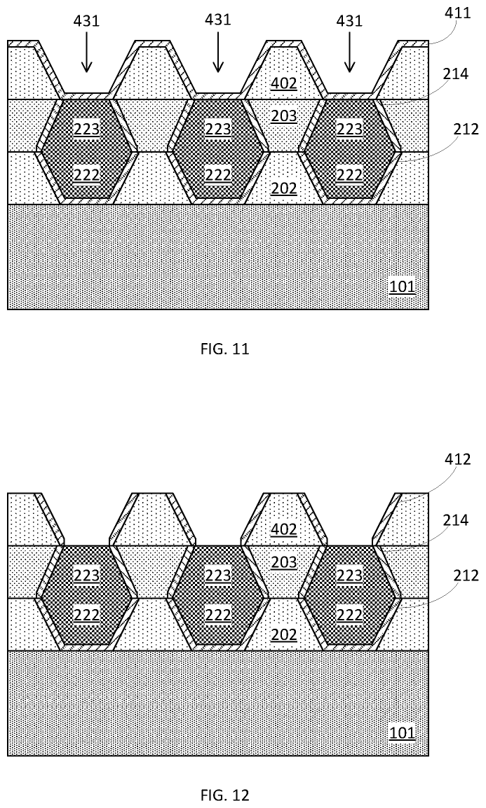

FIG. 11 is a demonstrative illustration of cross-sectional view of a wiring structure in a step of manufacturing thereof according to one embodiment of a method of present invention. More particularly, following the step illustrated in FIG. 10, embodiments of present invention provide removing the third hard mask 501 through, for example, a resist lifting process, and subsequently forming a third raw barrier layer 411 covering the third dielectric layer 402 and exposed top surfaces of the second section 223. The third raw barrier layer 411 may be a conformal layer of, for example, TiN, TaN, ZrN, TiZrN and may be formed through an ALD process. The third raw barrier layer 411 may be formed to be materially same or different from the first raw barrier layer 211 and the second raw barrier layer 213. The third raw barrier layer 411 may prevent conductive material of a third section of the metal line, to be formed in the openings 431 as being described below in more details, from diffusing into the third dielectric layer 402.

FIG. 12 is a demonstrative illustration of cross-sectional view of a wiring structure in a step of manufacturing thereof according to one embodiment of a method of present invention. More particularly, following the step illustrated in FIG. 11, embodiments of present invention provide applying a directional etching process that selectively removes portions of the third raw barrier layer 411 that are substantially horizontal. For example, the directional etching process may remove portions of the third raw barrier layer 411 that are on top of the third dielectric layer 402 and on the exposed top surfaces of the second section 223, thereby creating a third barrier layer 412 lining sidewalls of the openings 431. In one embodiment, since the bottoms of the openings 431 have significantly same size as the top surfaces of the second section 223, the second barrier layer 214 may extend continuously into the third barrier layer 412. In other words, the third barrier layer 412 may continue from the second barrier layer 214.

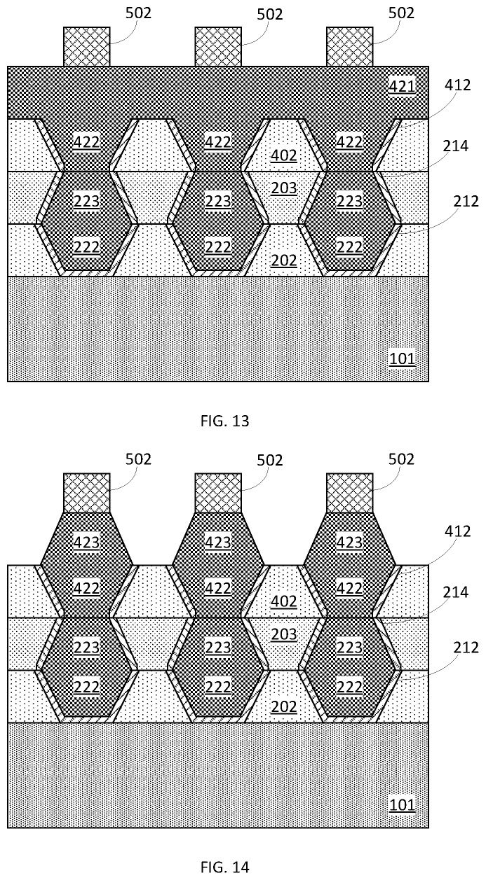

FIG. 13 is a demonstrative illustration of cross-sectional view of a wiring structure in a step of manufacturing thereof according to one embodiment of a method of present invention. More particularly, following the step illustrated in FIG. 12, embodiments of present invention provide depositing a conductive material into the openings 431 to form a third section 422 of the metal line. The conductive material of the third section 422 may be, for example, Ru, Mo, Ir, Co, or W. By following the shapes of the openings 431, a cross-section of the third section 422 may have a trapezoidal shape with a short base at a bottom and a long base at a top. The slant left sidewall of the third section 422 and the normal to the bottom surface of the first section 222 may form an angle P1, similar to the angle P1 illustrated in FIG. 2, that may be between −30 degrees and −45 degrees. The slant right sidewall of the third section 422 and the normal to the bottom surface of the first section 222 may form an angle P2, similar to the angle P2 illustrated in FIG. 2, that may be between 30 degrees and 45 degrees. In other words, the third section 422 may have a first sidewall (e.g., the left sidewall) and a second sidewall (e.g., the right sidewall) that lean outwards from a bottom to a top of the third section 422. In one embodiment, the first and second sidewalls of the third section 422 may extends continuously from the first and second sidewalls of the second section 223 respectively. In other words, the first and second sidewalls of the second section 223 may extend continuously into the first and second sidewalls of the third section 422 respectively.

Embodiments of present invention provide further depositing a conductive layer 421 on top of the third section 422 and above the third dielectric layer 402. The conductive layer 421 may be made of a same conductive material as that of the third section 422. However, embodiments of present invention are not limited in this aspect and different conductive material may be used for the conductive layer 421 and the third section 422.

After forming the conductive layer 421, embodiments of present invention provide forming a fourth hard mask 502 on top of the conductive layer 421. The fourth hard mask 502 may be formed to be significantly aligned with the bottom surface of the third section 422, or the bottom surface of the first section 222, and may be made to have a width that is about the same as a width of the bottom surface of the third section 422, or the bottom surface of the first section 222.

FIG. 14 is a demonstrative illustration of cross-sectional view of a wiring structure in a step of manufacturing thereof according to one embodiment of a method of present invention. More particularly, following the step illustrated in FIG. 13, embodiments of present invention provide forming a fourth section 423 of the metal line through a subtractive patterning process by etching portions of the conductive layer 421 that are not covered by the fourth hard mask 502 until the underneath third dielectric layer 402 is exposed. The formed fourth section 423 may have slant sidewalls such as a slant left sidewall and a slant right sidewall as is illustrated in FIG. 14.

In one embodiment, the slant sidewalls of the fourth section 423 may form angles with the normal to the bottom surface of the first section 222. For example, as being similarly illustrated in FIG. 5, the slant left sidewall of the fourth section 423 and the normal to the bottom surface of the first section 222 may form an angle Q1 between 30 degrees and 45 degrees, and the slant right sidewall of the fourth section 423 and the normal to the bottom surface of the first section 222 may form an angle Q2 between −30 degrees and −45 degrees. The fourth section 423 may have a trapezoidal shape with a long base at a bottom and a short base at a top, and may have first and second sidewalls (e.g., the left sidewall and the right sidewall) that lean inwards from a bottom to a top of the fourth section 423.

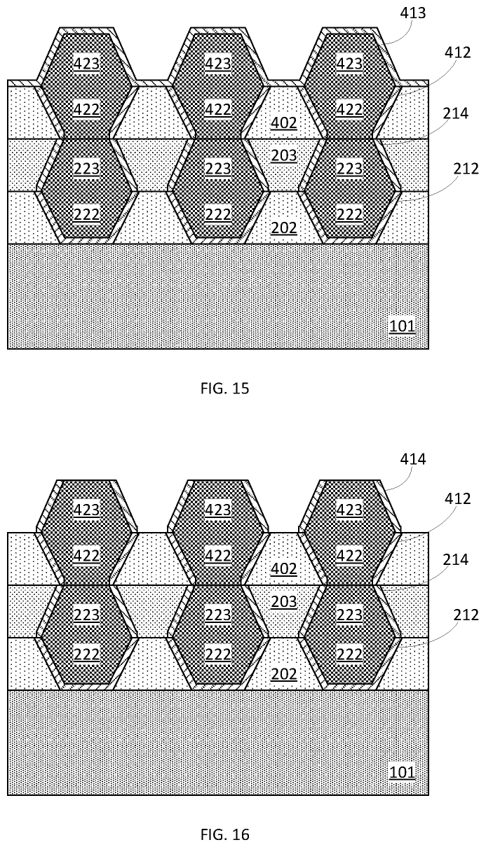

FIG. 15 is a demonstrative illustration of cross-sectional view of a wiring structure in a step of manufacturing thereof according to one embodiment of a method of present invention. More particularly, following the step illustrated in FIG. 14, embodiments of present invention provide removing the fourth hard mask 502 through, for example, a resist lifting process, and subsequently forming a fourth raw barrier layer 413 covering the fourth section 423 and the exposed top surfaces of the third dielectric layer 402. The fourth raw barrier layer 413 may be a conformal layer of, for example, TiN, TaN, ZrN, TiZrN and may be formed through an ALD process. In one embodiment, the fourth raw barrier layer 413 may be materially different from the first raw barrier layer 211, the second raw barrier layer 213, and the third raw barrier layer 411. The fourth raw barrier layer 411 may prevent conductive material of the fourth section 423 from diffusing into a fourth dielectric layer, that is to be formed to surround the fourth section 423 as being described below in more details.

FIG. 16 is a demonstrative illustration of cross-sectional view of a wiring structure in a step of manufacturing thereof according to one embodiment of a method of present invention. More particularly, following the step illustrated in FIG. 15, embodiments of present invention provide applying a directional etching process that selectively removes portions of the fourth raw barrier layer 413 that are substantially horizontal. For example, the directional etching process may remove portions of the fourth raw barrier layer 413 that are on a top surface of the fourth section 423 and are on top of the third dielectric layer 402, thereby creating a fourth barrier layer 414 that surrounds the sidewalls of the fourth section 423. In one embodiment, since the bottom surface of the fourth section 423 is significantly same in size as the top surface of the third section 422, the third barrier layer 412 may extend continuously into the fourth barrier layer 414. Similarly, the first and second sidewalls of the third section 422 may extend continuously into the first and second sidewalls of the fourth section 423.

FIG. 17 is a demonstrative illustration of cross-sectional view of a wiring structure in a step of manufacturing thereof according to one embodiment of a method of present invention. More particularly, following the step illustrated in FIG. 16, embodiments of present invention provide forming a fourth dielectric layer 403 surrounding, via the fourth barrier layer 414, sidewalls of the fourth section 423. For example, the fourth dielectric layer 403 may be formed through a selective deposition process where dielectric material of the fourth dielectric layer 403 may be formed selectively on top of the exposed third dielectric layer 402 and on top of barrier layer 414 and not, at least not meaningfully, on top of the top surface of the fourth section 423. However, embodiments of present invention are not limited in this aspect. For example, the fourth dielectric layer 403 may be formed through one or more other processes such as a CVD process, a PECVD process, an ALD process, or a PVD process. After the selective deposition process of the fourth dielectric layer 403, a CMP process may be applied to planarize the top surface of the fourth dielectric layer 403 and make the top surface of the fourth dielectric layer 403 coplanar with the top surface of the fourth section 423. The fourth dielectric layer 403 may be materially different from the third dielectric layer 402. For example, the third dielectric layer 402 may be SiCOH and the fourth dielectric layer 403 may be SiCNOH.

As is demonstratively illustrated in FIG. 17, embodiments of present invention provide forming a wiring structure 10 that may include one or more metal lines such as metal lines 610, 620, and 630. Metal lines 610, 620, and 630 may be multifaceted to include multiple sections such as a first section 222, a second section 223, a third section 422, and a fourth section 423. Each section of the metal lines may have a first sidewall such as a left sidewall and a second sidewall such as a right sidewall that extend either inwards or outwards from a bottom to a top of the section. Consequently, for example, the metal line 630 may have a left sidewall that is concatenated from the left sidewalls of the first, second, third and fourth sections 222, 223, 422, 423 and may have a right sidewall that is concatenated from the right sidewalls of the first, second, third and fourth sections 222, 223, 422, 423 of the metal line 630. As is demonstratively illustrated in FIG. 17, the first and right sidewalls of the metal line 630 may have a zigzag shape and are not straight in the vertical direction. By being in zigzag shapes, the metal lines 610, 620, and 630 may be able to maintain a reasonable width from a bottom to a top thereof, with small variations, while having a high aspect ratio. For example, the inward-leaning sidewalls of the second section 223 may return the width of the metal line 610 at the top of the second section 223 to approximately the width of the metal line at the bottom of the first section 222, thereby avoiding creating a metal line structure that, otherwise, may have a continuously expanding width from a bottom to a top thereof.

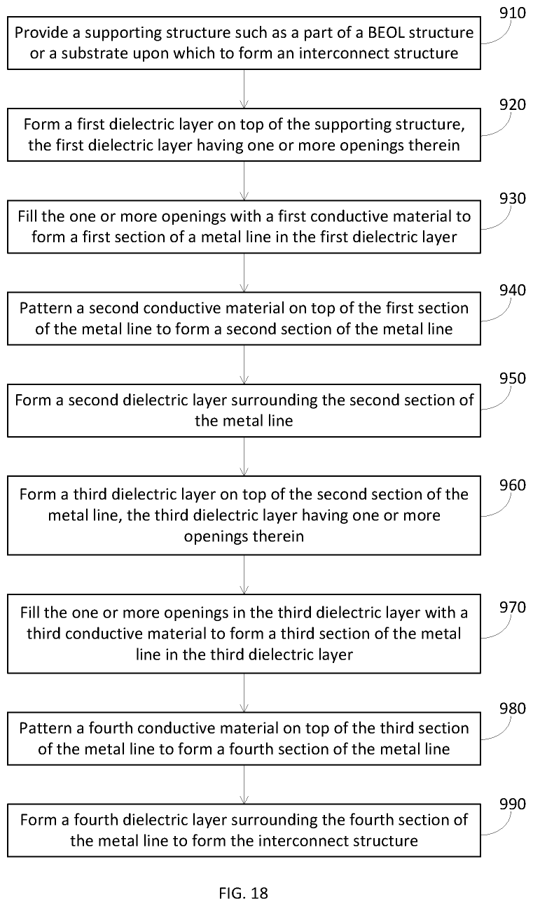

FIG. 18 is a demonstrative illustration of a flow-chart of a method of manufacturing a wiring structure according to embodiments of a method of present invention. The method includes (910) providing a supporting structure such as a part of a BEOL structure or a semiconductor substrate upon which to form the wiring structure; (920) forming a first dielectric layer on top of the supporting structure, the first dielectric layer having one or more openings therein; (930) filling the one or more openings with a first conductive material to form a first section of a metal line in the first dielectric layer; (940) patterning a second conductive material on top of the first section of the metal line to form a second section of the metal line; (950) forming a second dielectric layer surrounding the second section of the metal line; (960) forming a third dielectric layer on top of the second section of the metal line, the third dielectric layer having one or more openings therein; (970) filling the one or more openings in the third dielectric layer with a third conductive material to form a third section of the metal line in the third dielectric layer; (980) patterning a fourth conductive material on top of the third section of the metal line to form a fourth section of the metal line; and (990) forming a fourth dielectric layer surrounding the fourth section of the metal line, thereby forming the wiring structure.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A wiring structure comprising a metal line in a dielectric layer, the metal line having a first sidewall and a second sidewall opposite the first sidewall, the first and second sidewalls having a zigzag shape and not being straight along a vertical direction.

2. The wiring structure of claim 1, wherein the metal line, from a bottom to a top thereof, includes at least a first section and a second section with their respective first and second sidewalls, wherein the first and second sidewalls of the first section lean outwards from a bottom to a top of the first section, and the first and second sidewalls of the second section lean inwards from a bottom to a top of the second section.

3. The wiring structure of claim 2, wherein the metal line further comprises a third section directly above the second section and a fourth section directly above the third section, wherein the third section includes first and second sidewalls, and the first and second sidewalls of the third section lean outwards from a bottom to a top of the third section, and the fourth section includes first and second sidewalls, and the first and second sidewalls of the fourth section lean inwards from a bottom to a top of the fourth section.

4. The wiring structure of claim 3, wherein the first and second sidewalls of the first section extend continuously into the first and second sidewalls of the second section, the first and second sidewalls of the second section extend continuously into the first and second sidewalls of the third section, and the first and second sidewalls of the third section extend continuously into the first and second sidewalls of the fourth section.

5. The wiring structure of claim 3, wherein the first sidewall of the first section forms an angle between −30 degrees and −45 degrees with a normal to a bottom surface of the first section, and the second sidewall of the first section forms an angle between 30 degrees and 45 degrees with the normal to the bottom surface of the first section.

6. The wiring structure of claim 3, wherein the first section, the second section, the third section, and the fourth section are surrounded, respectively, by a first dielectric layer, a second dielectric layer, a third dielectric layer, and a fourth dielectric layer, wherein the first dielectric layer is materially different from the second dielectric layer, the second dielectric layer is materially different from the third dielectric layer, and the third dielectric layer is materially different from the fourth dielectric layer.

7. The wiring structure of claim 6, further comprising a first barrier layer between the first section and the first dielectric layer and a second barrier layer between the second section and the second dielectric layer, wherein the first barrier layer is materially different from the second barrier layer.

8. The wiring structure of claim 7, wherein the first barrier layer is made of titanium-nitride and the second barrier layer is made of tantalum-nitride.

9. A method of forming a wiring structure, the method comprising:
filling one or more openings in a first dielectric layer with a first conductive material to form a first section of a metal line in the first dielectric layer;
patterning a second conductive material on top of the first section of the metal line to form a second section of the metal line;
forming a second dielectric layer surrounding the second section of the metal line;
forming a third dielectric layer on top of the second section of the metal line, the third dielectric layer having one or more openings therein;
filling the one or more openings in the third dielectric layer with a third conductive material to form a third section of the metal line in the third dielectric layer;
patterning a fourth conductive material on top of the third section of the metal line to form a fourth section of the metal line; and
forming a fourth dielectric layer surrounding the fourth section of the metal line, thereby forming the metal line of the wiring structure.

10. The method of claim 9, wherein forming the first dielectric layer comprises etching a raw dielectric layer to create the one or more openings, the one or more openings having slant sidewalls that extend outwards from a bottom to a top of the one or more openings.

11. The method of claim 9, further comprising, before filling the one or more openings in the first dielectric layer with the first conductive material, forming a first raw barrier layer lining sidewalls and bottoms of the one or more openings in the first dielectric layer.

12. The method of claim 9, wherein patterning the second conductive material comprises etching the second conductive material to form the second section of the metal line, the second section of the metal line having slant sidewalls that lean inwards from a bottom to a top of the second section.

13. The method of claim 9, further comprising, before forming the second dielectric layer, forming a second barrier layer surrounding sidewalls of the second section of the metal line.

14. The method of claim 13, wherein forming the second barrier layer comprises forming a second raw barrier layer covering the second section of the metal line and a top surface of the first dielectric layer, and selectively removing horizontal portions of the second raw barrier layer to create the second barrier layer.

15. The method of claim 9, wherein forming the second dielectric layer comprises selectively depositing the second dielectric layer to surround sidewalls of the second section of the metal line.

16. A wiring structure comprising a metal line in a dielectric layer, the metal line having a first sidewall and a second sidewall opposite the first sidewall and, from a bottom to a top thereof, including at least a first section and a second section with their respective first and second sidewalls, wherein the first and second sidewalls of the first section lean outwards from a bottom to a top of the first section, and the first and second sidewalls of the second section lean inwards from a bottom to a top of the second section.

17. The wiring structure of claim 16, wherein the metal line further includes a third section directly above the second section and a fourth section directly above the third section, wherein the third section has its first and second sidewalls and the first and second sidewalls of the third section lean outwards from a bottom to a top of the third section, and the fourth section has its first and second sidewalls and the first and second sidewalls of the fourth section lean inwards from a bottom to a top of the fourth section.

18. The wiring structure of claim 17, wherein the first section, the second section, the third section, and the fourth section are surrounded by a first barrier layer, a second barrier layer, a third barrier layer, and a fourth barrier layer respectively, wherein the first barrier layer is materially different from the second barrier layer, the second barrier layer is materially different from the third barrier layer, and the third barrier layer is materially different from the fourth barrier layer.

19. The wiring structure of claim 18, wherein the first barrier layer is made of titanium-nitride, the second barrier layer is made of tantalum-nitride, the third barrier layer is made of zirconium-nitride, and the fourth barrier layer is made of titanium-zirconium-nitride.

20. The wiring structure of claim 18, wherein the first section, the second section, the third section, and the fourth section of the metal line are made of a same material, the same material being ruthenium, molybdenum, Iridium, cobalt, or tungsten.
